(19) United States
(12) Patent Application Publication
(10) Pub. No.: US 2025/0212538 A1
(43) Pub. Date: Jun. 26, 2025

(54) SEMICONDUCTOR DEVICE

(71) Applicant: SONY SEMICONDUCTOR SOLUTIONS CORPORATION, KANAGAWA (JP)

(72) Inventors: KOUSUKE SEKI, KANAGAWA (JP); SHUN MITARAI, KANAGAWA (JP); KIWAMU ADACHI, KANAGAWA (JP); TAKAHIRO IGARASHI, KANAGAWA (JP)

(21) Appl. No.: 18/848,719

(22) PCT Filed: Feb. 8, 2023
(86) PCT No.: PCT/JP2023/004246

§ 371 Date: Sep. 19, 2024

(30) Foreign Application Priority Data
Mar. 29, 2022 (JP) 2022-054197

(51) Int. Cl. H10F 39/00; H01L 23/10; H01L 23/15; H10F 39/18

(52) U.S. Cl. CPC H10F 39/804; H01L 23/10; H10F 39/014; H10F 39/811; H01L 23/15; H10F 39/18

(57) ABSTRACT

There is provided a semiconductor device that can reduce a stress to be applied to a glass substrate, and sufficiently protect end parts of the glass substrate. A semiconductor device according to the present disclosure includes: a glass substrate that includes a first face, a second face on a side opposite to the first face, and a first side face between the first face and the second face; a semiconductor chip that is provided on the first face; a frame that includes a first facing face facing an outer edge part of the first face, and a second facing face facing the first side face; and a first material film that is provided at least partially between the glass substrate and the frame.

### TECHNICAL FIELD

The present disclosure relates to a semiconductor device.

### BACKGROUND ART

A glass substrate can be applied a semiconductor processing technique and has high surface flatness, and therefore is promising as a semiconductor device substrate such an optical part or a high frequency part. To practically use the glass substrate as a semiconductor substrate, it is necessary to maintain flatness of the glass substrate and prevent cracking of end parts. Hence, it is important to protect the glass substrate.

### CITATION LIST

### Patent Literature

### PTL 1

JP 2020-155717A

### PTL 2

JP 2020-035925A

### PTL 3

JP 2017-188621A

### PTL 4

JP 2019-016684A

### PTL 5

JP 2017-103478A

### PTL 6

JP 2017-139258A

### PTL 7

JP 2020-072110A

### PTL 8

JP 2020-074434A

### SUMMARY

### Technical Problem

When, for example, a Complementary Metal Oxide Semiconductor (CMOS) image sensor is mounted on a glass substrate, transportation, handling, or the like in an assembly process may crack or chip end parts of the glass substrate. Such cracking or chipping of the glass substrate lowers reliability of a semiconductor device.

Hence, the present disclosure provides a semiconductor device that can reduce a stress to be applied to a glass substrate, and sufficiently protect end parts of the glass substrate.

### Solution to Problem

A semiconductor device according to one aspect of the present disclosure includes: a glass substrate that includes a first face, a second face on a side opposite to the first face, and a first side face between the first face and the second face; a semiconductor chip that is provided on the first face; a frame that includes a first facing face facing an outer edge part of the first face, and a second facing face facing the first side face; and a first material film that is provided at least partially between the glass substrate and the frame.

The frame covers a first end part between the first face and the first side face of the glass substrate, and over an entire outer periphery of the first face.

The frame extends to a lower side compared to the second face along the first side face from a first end part between the first face and the first side face of the glass substrate to a second end part between the second face and the first side face of the glass substrate.

The frame extends to a middle of the first side face along the first side face from a first end part between the first face and the first side face of the glass substrate to a second end part between the second face and the first side face of the glass substrate.

The first material film is provided at the first end part between the first face and the first side face of the glass substrate and over an entire outer periphery of the glass substrate.

The semiconductor chip is a CMOS Image Sensor (CIS), and a region of the frame facing a center part of the first face is provided with an opening part.

The first material film extends to a lower side compared to the second face along the first side face from a first end part between the first face and the first side face of the glass substrate to a second end part between the second face and the first side face of the glass substrate.

The first material film extends to an upper side of the second surface along the first side face from a first end part between the first face and the first side face of the glass substrate to a second end part between the second face and the first side face of the glass substrate.

The semiconductor device further includes a second wiring provided on the second face, and the first material film covers part of the second end part and the second wiring.

The semiconductor device further includes a second wiring provided on the second face, and the first material film covers the second end part, and does not reach the second wiring.

The frame includes a hole that penetrates from an outside in the first facing face, the second facing face, or a corner part between the first facing face and the second facing face.

The frame includes at part of the first facing face a protrusion part that protrudes toward the first face of the glass substrate.

The first facing face of the frame is substantially parallel to the first face of the glass substrate, and the second facing face of the frame is substantially parallel to the second face of the glass substrate.

The first facing face of the frame is inclined with respect to the first face to approach the first face of the glass substrate from the first end part of the glass substrate to a center of the first face.

A plurality of the glass substrates are laminated.

The glass substrate includes a trench provided in the first face or the second face.

The first material film is provided substantially coplanarly to the second face of the glass substrate.

A manufacturing method for a semiconductor device according to one aspect of the present disclosure includes: mounting a semiconductor chip on a first face of a glass substrate that includes the first face, a second face on a side opposite to the first face, and a first side face between the first face and the second face; supplying a first material film to a first facing face of a frame including the first facing face and a second facing face; and adhering the glass substrate and the frame using the first material film such that the first facing face faces an outer edge part of the first face, and the second facing face faces the first side face.

The manufacturing method for the semiconductor device further includes attaching the glass substrate onto a support member, and when the semiconductor chip and the frame are adhered, the glass substrate on the support member is directed and adhered to the frame using the first material film.

When the semiconductor chip and the frame are adhered, the support member makes the first material film substantially coplanarly to the second face of the glass substrate.

A plurality of the glass substrates are attached to the support member, the frame includes an opening part at a position meeting each of the plurality of glass substrates, and when the semiconductor chip and the frame are adhered, the plurality of glass substrates on the support member are directed and adhered to the opening part of the frame using the first material film.

### BRIEF DESCRIPTION OF DRAWINGS

FIG. 1 is a schematic plan view illustrating a configuration example of a semiconductor device according to a first embodiment.

FIG. 2 is a schematic cross-sectional view illustrating the configuration example of the semiconductor device according to the first embodiment.

FIG. 3 is a schematic cross-sectional view illustrating a configuration example of the semiconductor device according to a second embodiment.

FIG. 4 is a partial cross-sectional view illustrating the configuration example of the semiconductor device according to the second embodiment.

FIG. 5 is a schematic cross-sectional view illustrating a configuration example of the semiconductor device according to a third embodiment.

FIG. 6 is a partial cross-sectional view illustrating the configuration example of the semiconductor device according to the third embodiment.

FIG. 7 is a schematic plan view illustrating a configuration example of the semiconductor device according to a fourth embodiment.

FIG. 8 is a schematic cross-sectional view illustrating the configuration example of the semiconductor device according to the fourth embodiment.

FIG. 9 is a schematic cross-sectional view illustrating a configuration example of the semiconductor device according to a fifth embodiment.

FIG. 10 is a schematic cross-sectional view illustrating a configuration example of the semiconductor device according to a sixth embodiment.

FIG. 11 is a schematic cross-sectional view illustrating a configuration example of the semiconductor device according to a seventh embodiment.

FIG. 12 is a schematic cross-sectional view illustrating a configuration example of the semiconductor device according to an eighth embodiment.

FIG. 13 is a partial cross-sectional view illustrating the configuration example of the semiconductor device according to the eighth embodiment.

FIG. 14 is a schematic plan view illustrating a configuration example of the semiconductor device according to a ninth embodiment.

FIG. 15 is a cross-sectional view illustrating an example of a manufacturing method for the semiconductor device according to the first embodiment.

FIG. 16 is a cross-sectional view illustrating an example of the manufacturing method for the semiconductor device continuing from FIG. 15.

FIG. 17 is a cross-sectional view illustrating an example of the manufacturing method for the semiconductor device continuing from FIG. 16.

FIG. 18 is a cross-sectional view illustrating an example of the manufacturing method for the semiconductor device continuing from FIG. 17.

FIG. 19 is a cross-sectional view illustrating a state where a material of a liquid adhesive layer is supplied onto a facing surface of a frame according to the manufacturing method according to the fifth embodiment.

FIG. 20 is a cross-sectional view illustrating a state where a material of a liquid adhesive layer is supplied onto the facing surface of the frame according to the manufacturing method according to the sixth embodiment.

FIG. 21 is a cross-sectional view illustrating an example of the manufacturing method for the semiconductor device according to the ninth embodiment.

FIG. 22 is a cross-sectional view illustrating an example of the manufacturing method for the semiconductor device continuing from FIG. 21.

FIG. 23 is a cross-sectional view illustrating an example of the manufacturing method for the semiconductor device continuing from FIG. 22.

FIG. 24 is a cross-sectional view illustrating an example of the manufacturing method for the semiconductor device continuing from FIG. 23.

FIG. 25 is a plan view illustrating an example of an aggregate of the frames.

FIG. 26 is a cross-sectional view taken along line 26-26 in FIG. 25.

FIG. 27 is a view illustrating another example of the manufacturing method for the semiconductor device according to the first embodiment.

FIG. 28 is a cross-sectional view illustrating an example of the manufacturing method for the semiconductor device continuing from FIG. 27.

FIG. 29 is a cross-sectional view illustrating an example of the manufacturing method for the semiconductor device continuing from FIG. 28.

FIG. 30 is a cross-sectional view illustrating an example of the manufacturing method for the semiconductor device continuing from FIG. 29.

FIG. 31 is a view illustrating an example where the embodiments are used as a CMOS image sensor.

### DESCRIPTION OF EMBODIMENTS

Hereinafter, specific embodiments to which the present technology is applied will be described in detail with reference to the drawings. The drawings are schematic or conceptual, and the ratio and the like of each part are not necessarily the same as the actual one. In the specification and drawings, the same reference numerals are given to the same elements as those described above with respect to the previous drawings, and detailed description thereof will be omitted as appropriate.

### First Embodiment

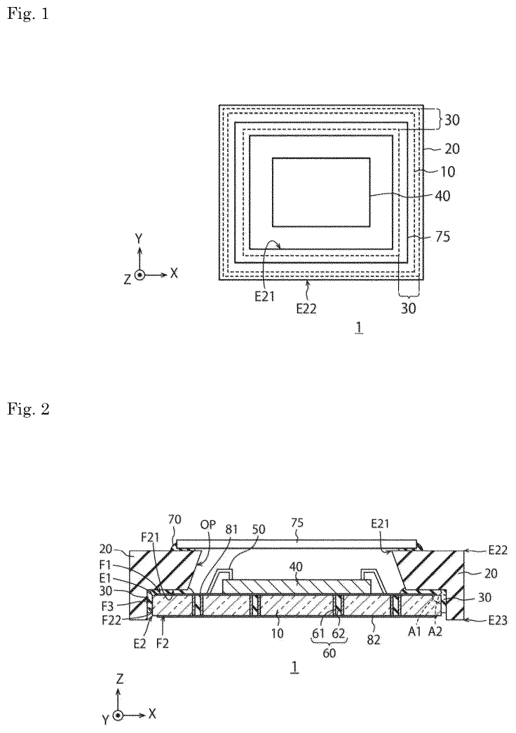

FIG. 1 is a schematic plan view illustrating a configuration example of a semiconductor device 1 according to the first embodiment. FIG. 2 is a schematic cross-sectional view illustrating the configuration example of the semiconductor device 1 according to the first embodiment. Note that FIG. 1 illustrates a positional relationship between a glass substrate 10, a frame 20, an adhesive layer 30, a semiconductor chip 40, and a cover glass 75.

As illustrated in FIG. 1, the semiconductor chip 40 is mounted on a center part of the glass substrate 10. The frame 20 is adhered to an outer edge part of the glass substrate 10 with the adhesive layer 30 interposed therebetween. The frame 20 covers the outer edge part of the glass substrate 10 over an entire outer periphery of the outer edge part. Furthermore, the adhesive layer 30 is also provided between the frame 20 and the outer edge part of the glass substrate 10 and over the entire outer periphery of the glass substrate 10. The frame 20 is provided continuously covering the top surface and the side faces of the glass substrate 10. The cover glass 75 is adhered onto the frame 20 to cover the upper side of the semiconductor chip 40.

As illustrated in FIG. 2, the semiconductor device 1 includes the glass substrate 10, the frame 20, the adhesive layer 30, the semiconductor chip 40, an adhesive layer 70, and the cover glass 75.

The glass substrate 10 includes a first face F1, a second face F2 on a side opposite to the first face F1, and a side face (first side face) F3 between the first face F1 and the second face F2. The glass substrate 10 may be a single layer substrate, may be a laminated glass substrate, or may be made of ceramics. A wiring part 81 is provided on the first face F1. The wiring part 81 includes a plurality of layers of wirings (not illustrated) provided on the first face F1. These wirings are covered with an insulating film (not illustrated). A wiring part 82 is provided on the second face F2. The wiring part 82 includes a plurality of layers of wirings (not illustrated) provided on the second face F2. These wirings are covered with an insulating film (not illustrated). For the wirings, a low-resistance metal material such as copper is used.

The glass substrate 10 is provided with through-electrodes 60. The through-electrode 60 includes a metal film 61 that covers an inner wall of a through-hole (Through Glass Via (TGV)) that penetrates between the first face F1 and the second face F2 of the glass substrate 10, and an insulating film 62 that is filled inside of the metal film 61. For the metal film 61, for example, a low-resistance metal material such as copper is used. The metal film 61 preferably continuously continues to the wirings on the first and second faces F1 and F2 of the glass substrate 10, and is formed of the same material as those of the wirings. The metal film 61 is provided to electrically connect the wiring of the wiring part 81 of the first face F1 and the wiring of the wiring part 82 of the second face F2 via the via. The insulating film 62 preferably continuously connects to an insulating film (not illustrated) that covers the wirings of the wiring parts 81 and 82, and is formed of the same material as that of this insulating film. For example, an insulation material such as an epoxy resin is used for the insulating film 62. Consequently, the insulating film 62 can be simultaneously formed in the same process as that of the insulating film that covers the wirings of the wiring parts 81 and 82 on the first face F1 and the second face F2 of the glass substrate 10, and formed as a seamlessly continuing insulating film. The wirings of the wiring parts 81 and 82 and the metal film 61 seamlessly cover the surroundings of an opening end from the inner wall of the via. Furthermore, the insulating film that covers the wiring parts 81 and 82 and the insulating film 62 in the through-hole are continuously provided seamlessly from the inside to the outside of the via. Consequently, it is possible to reduce a stress produced in a TGV processing surface and enhance the TGV, and improve TGV strength.

An unillustrated wiring and insulating film may be further provided on the first face F1 of the glass substrate 10. Thus, the wiring parts 81 and 82 have multilayer wiring structures. The wiring parts 81 and 82 may be connected with an electrode pad and a bonding pad.

The semiconductor chip 40 is mounted on the glass substrate 10. The semiconductor chip 40 is electrically connected to the wirings of the wiring parts 81 and 82 via a bonding wire 50. The semiconductor chip 40 is adhered onto the glass substrate 10 or the wiring part 81 above the glass substrate 10 by an adhesive (not illustrated). The semiconductor chip 40 is not particularly limited, and may be, for example, a CMOS Image Sensor (CIS).

Furthermore, the frame 20 is adhered onto the glass substrate 10 by the adhesive layer 30. The frame 20 includes a first facing face F21 that faces an outer edge part of the first face F1 of the glass substrate 10, and a second facing face F22 that faces the side face F3. The first facing face F21 is substantially parallel to the first face F1, and faces the first face F1 sandwiching the adhesive layer 30 therebetween. The second facing face F22 is substantially parallel to the side face F3, and faces the side face F3 sandwiching the adhesive layer 30 therebetween. Hence, a first angle A1 formed by the first face F1 and the side face F3 of the glass substrate 10, and a second angle A2 formed by the first facing face F21 and the second facing face F22 of the frame 20 are substantially equal. When, for example, the first angle A1 is a substantially right angle, the second angle A2 is also a substantially right angle. The frame 20 may be, for example, a resin, ceramics, or the like.

Furthermore, the glass substrate 10 has, for example, a substantially square shape in plan view from a Z direction illustrated in FIG. 1. The frame 20 is provided over the entire outer periphery of the glass substrate 10 in plan view from the Z direction, and covers the outer edge part of the glass substrate 10. Hence, when the glass substrate 10 has the substantially square shape, the frame 20 has a frame shape of a square shape substantially similar to the glass substrate 10. An inner edge E21 of the frame 20 is located on an inner side of the outer edge of the glass substrate 10, and an outer edge E22 of the frame 20 is located on an outer side of the outer edge of the glass substrate 10.

The frame 20 surrounds the surroundings of the semiconductor chip 40, and includes an opening part OP in a region that opposes to a center part of the first face F1 of the glass substrate 10. Incident light enters the semiconductor chip 40 through the opening part OP.

In the present embodiment, a lower end E23 of the frame 20 illustrated in FIG. 2 is located on a lower side (−Z direction) compared to the second face F2 of the glass substrate 10. The frame 20 extends to a lower side compared to the second face F2 along the side face F3 from an end part (first end part) E1 of the first face F1 of the glass substrate 10 to an end part (second end part) E2 of the second face F2. That is, the lower end E23 of the frame 20 protrudes in the −Z direction compared to the second face F2 of the glass substrate 10.

The adhesive layer 30 is provided at least partially between the first facing face F21 of the frame 20 and the first face F1 of the glass substrate 10. Alternatively, the adhesive layer 30 is provided at least partially between the second facing face F22 of the frame 20 and the side face F3 of the glass substrate 10. In the present embodiment, the adhesive layer 30 fills the entirety between the first facing face F21 of the frame 20 and the first face F1 of the glass substrate 10, and protrudes a little toward a semiconductor chip 40 side. Furthermore, the adhesive layer 30 extends from the end part E1 to the end part E2 between the second facing face F22 of the frame 20 and the side face F3 of the glass substrate 10, yet does not fill the entirety, and does not protrude in the −Z direction from the end part E2 or the end part E23. That is, the adhesive layer 30 stops in the middle of the side face F3 from the end part E1 to the end part E2 along the side face F3, and extends up to a position above the second face F2. The cover glass 75 is provided on the opening part OP of the frame 20 so as to cover the upper side of the semiconductor chip 40. The cover glass 75 is adhered around the opening part OP of the frame 20 and with the adhesive layer 70 interposed therebetween. Incident light transmits through the cover glass 75 and enters the semiconductor chip 40.

In the present embodiment, as illustrated in FIG. 1, the adhesive layer 30 is also provided over the entire outer periphery of the glass substrate 10 in plan view from the Z direction, and the end part E1 between the first face F1 and the side face F3 of the glass substrate 10 is provided over the entire outer periphery of the glass substrate 10. However, the adhesive layer 30 may be provided at part of the outer periphery (the inner periphery of the frame 20) of the glass substrate 10. For example, the adhesive layer 30 may be provided at the four corners of the glass substrate 10.

For the adhesive layer 30, a thermoplastic resin such as a silicone-based resin or an epoxy-based resin is used. The adhesive layer 30 is preferably formed of a material having a lower elastic modulus than those of the glass substrate 10 and the frame 20. For example, the elastic modulus of the adhesive layer 30 is zero to four Gpa at a normal temperature. Consequently, the adhesive layer 30 can absorb the stress between the glass substrate 10 and the frame 20.

According to the present embodiment, the frame 20 is provided covering the end part E1 of the glass substrate 10, and is adhered to the glass substrate 10 by the adhesive layer 30. Consequently, the end part E1 of the glass substrate 10 is protected by the frame 20 to prevent cracking and chipping of the end part E1 of the glass substrate 10.

Furthermore, the end part E23 of the frame 20 extends in a lower direction (−Z direction) compared to the second face F2 of the glass substrate 10. Consequently, the frame 20 can also protect the end part E2 on a second face F2 side of the glass substrate 10, and prevent cracking and chipping of the end part E1 of the glass substrate 10.

Furthermore, for the adhesive layer 30, a low elastic modulus material having the low elastic modulus than those of the glass substrate 10 and the frame 20 is used. Consequently, the adhesive layer 30 can absorb the stress between the glass substrate 10 and the frame 20, and prevent warps of the glass substrate 10 and the frame 20. Consequently, it is easy to correct an assembly error of the semiconductor device 1.

### Second Embodiment

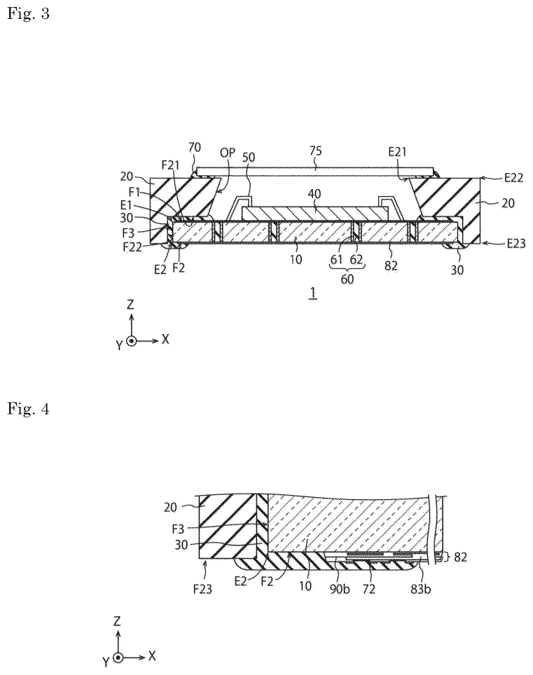

FIG. 3 is a schematic cross-sectional view illustrating a configuration example of the semiconductor device 1 according to the second embodiment. FIG. 4 is a partial cross-sectional view illustrating the configuration example of the semiconductor device 1 according to the second embodiment.

In the second embodiment, the adhesive layer 30 protrudes toward the second face F2 side of the glass substrate 10, and covers part of the wiring part 82 on the second face F2 side. That is, the adhesive layer 30 extends along the side face F3 from the end part E1 to the second end part E2 of the glass substrate 10, and extends to the lower side (−Z direction) compared to the second face F2. Furthermore, the adhesive layer 30 covers on the second face F2 part of the wiring part 82 that is close to the outer edge of the glass substrate 10. The adhesive layer 30 can cover the end part E2 of the glass substrate 10, and protect the end part E2, too.

As illustrated in FIG. 4, the wiring part 82 includes a wiring 83b, an insulation layer 90b, and an electrode pad 72. The wiring 83b is provided on the glass substrate 10, or is provided in the insulation layer 90b. The insulation layer 90b is provided on the glass substrate 10, and covers the wiring 83b. The electrode pad 72 is exposed from the insulation layer 90b, and is electrically connected to the wiring 83b.

The glass substrate 10 is exposed in a region that is not provided with the wiring part 82 at the outer edge part of the second face F2 of the glass substrate 10, and the region is covered by the adhesive layer 30. The adhesive layer 30 is in direct contact with the glass substrate 10 in this region.

According to the second embodiment, the adhesive layer 30 extends to the lower side compared to the second face F2, and covers the end part E2 of the glass substrate 10 and covers part of the wiring part 82 on the second face F2 of the glass substrate 10. Consequently, the adhesive layer 30 can protect the end part E2 and part of the wiring part 82 of the glass substrate 10.

The other configurations according to the second embodiment may be the same as those in the above first embodiment. Consequently, according to the second embodiment, it is also possible to obtain the same effects as those of the first embodiment.

### Third Embodiment

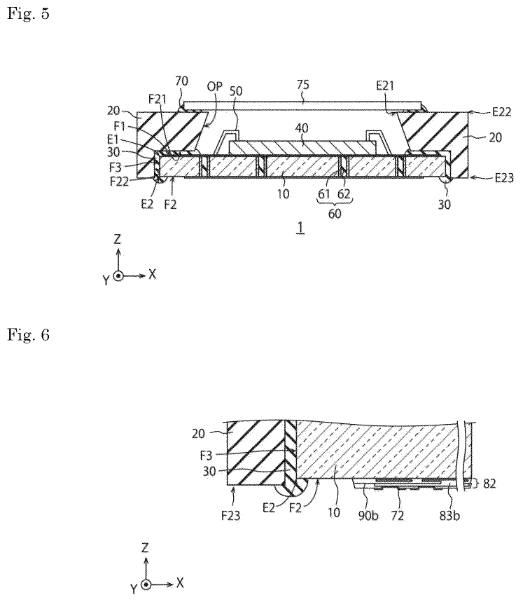

FIG. 5 is a schematic cross-sectional view illustrating a configuration example of the semiconductor device 1 according to the third embodiment. FIG. 6 is a partial cross-sectional view illustrating the configuration example of the semiconductor device 1 according to the third embodiment.

The third embodiment is the same as the second embodiment in that the adhesive layer 30 protrudes toward the second face F2 side of the glass substrate 10, and covers the end part E2 of the glass substrate 10 and the outer edge part of the second face F2. Consequently, the adhesive layer 30 can cover the end part E2 of the glass substrate 10, and protect the end part E2, too. However, in the third embodiment, the adhesive layer 30 does not reach the wiring part 82, and does not cover the wiring part 82.

The other configurations according to the third embodiment may be the same as those in the second embodiment. Consequently, according to the third embodiment, it is also possible to obtain the same effects as those of the second embodiment.

### Fourth Embodiment

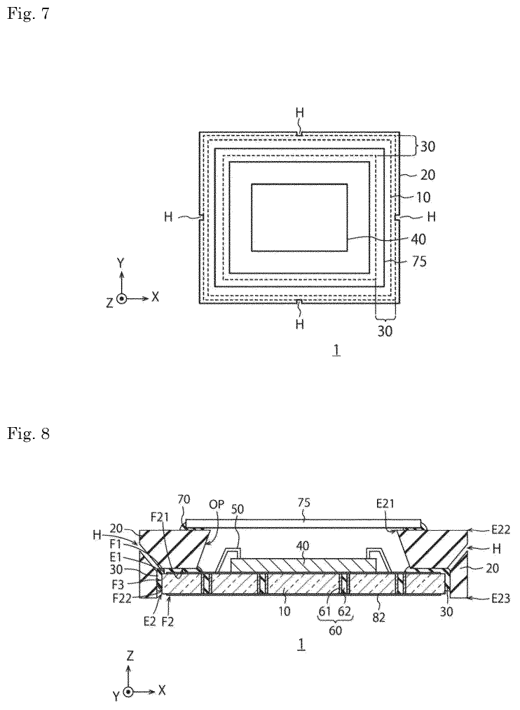

FIG. 7 is a schematic plan view illustrating a configuration example of the semiconductor device 1 according to the fourth embodiment. FIG. 8 is a schematic cross-sectional view illustrating the configuration example of the semiconductor device 1 according to the fourth embodiment.

In the fourth embodiment, the frame 20 includes holes H. As illustrated in FIG. 8, the hole H is a hole that penetrates from the outside of the frame 20 to the facing face F21 or F22. The holes H may penetrate from the outside a corner part between the facing face F21 and the facing face F22. The holes H reach the adhesive layer 30, and the adhesive layer 30 may enter the holes H.

The hole H functions an air hole (deaeration hole) when the frame 20 is adhered to the glass substrate 10. When the frame 20 is mounted on the glass substrate 10, a gas between the frame 20 and the glass substrate 10 is vented, so that the adhesive layer 30 stays between the frame 20 and the glass substrate 10 as much as possible, and makes the adhesive layer 30 hardly protrude from between the frame 20 and the glass substrate 10.

For example, contact of the adhesive layer 30 with the bonding wire 50 undermines reliability of the semiconductor device 1.

By contrast with this, in the present embodiment, when the frame 20 is mounted on the glass substrate 10, the holes H allow a gas between the frame 20 and the glass substrate 10 to be vented. Consequently, it is possible to prevent the adhesive layer 30 from protruding from between the frame 20 and the glass substrate 10, and prevent the adhesive layer 30 from contacting the bonding wire 50. Consequently, according to the fourth embodiment, it is possible to keep the reliability of the semiconductor device 1.

As illustrated in FIG. 7 the four holes H may be arranged at the center parts of the four sides of the frame 20 in plan view seen from the Z direction. However, arrangement of the holes H in plan view is not limited to this, and the holes H may be arranged at arbitrary positions of the frame 20. For example, the holes H may be provided at four corners of the frame 20. Furthermore, the number of the holes H is not limited to four, and may be five or more or may be three or less. On the other hand, the holes H are preferably arranged substantially evenly on the periphery of the frame 20. Consequently, the holes H can substantially evenly vent the gas from between the frame 20 and the glass substrate 10, and be prevented from locally protruding from between the frame 20 and the glass substrate 10.

The other configurations according to the fourth embodiment may be the same as those in one of the first to third embodiments. Consequently, according to the fourth embodiment, it is also possible to obtain the same effects as those of the first to third embodiments.

### Fifth Embodiment

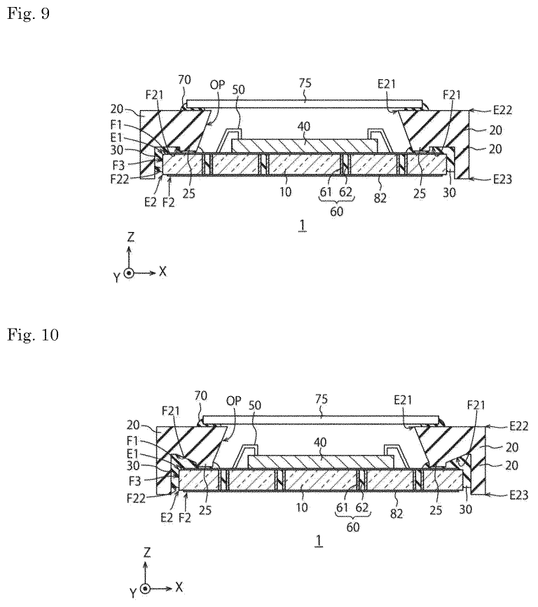

FIG. 9 is a schematic cross-sectional view illustrating a configuration example of the semiconductor device 1 according to the fifth embodiment.

In the fifth embodiment, part of the facing face F21 of the frame 20 includes protrusion parts 25 that protrude from the facing face F21 toward the first face F1 of the glass substrate 10. The protrusion part 25 is integrally formed using the same material as that of the frame 20, yet may be provided as a separate body from the frame 20 and attached to the frame 20.

A gap between the protrusion part 25 and the first face F1 is narrower than a distance between the facing face F21 and the first face F1. Consequently, when the frame 20 is adhered to the glass substrate 10, the protrusion parts 25 make the adhesive layer 30 stay between the frame 20 and the glass substrate 10 as much as possible, and make the adhesive layer 30 hardly protrude on the first face F1 from between the frame 20 and the glass substrate 10. Consequently, it is possible to prevent the adhesive layer 30 from contacting the bonding wire 50, and keep the reliability of the semiconductor device 1.

Furthermore, when the frame 20 is adhered to the glass substrate 10, the upper and lower sides of the frame 20 are reversed, and the facing face F21 is directed upward (+Z direction) (see FIG. 19). The material of the liquid adhesive layer 30 is supplied onto the facing face F21 of the frame 20. At this time, the protrusion parts 25 hold back the material of the liquid adhesive layer 30, and make the material of the adhesive layer 30 stay on the facing face F21. Consequently, when the frame 20 is adhered to the glass substrate 10, it is possible to prevent the material of the adhesive layer 30 from spilling over from the facing face F21 of the frame 20.

The other configurations according to the fifth embodiment may be the same as those in one of the first to fourth embodiments. Consequently, according to the fifth embodiment, it is also possible to obtain the same effects as those of the first to fourth embodiments.

### Sixth Embodiment

FIG. 10 is a schematic cross-sectional view illustrating a configuration example of the semiconductor device 1 according to the sixth embodiment.

The sixth embodiment is the same as the fifth embodiment in that part of the facing face F21 of the frame 20 includes the protrusion parts 25. On the other hand, in the sixth embodiment, the facing face F21 is inclined toward the first face F1. The facing face F21 is inclined to approach the first face F1 of the glass substrate 10 from the end part E1 of the glass substrate 10 to the center of the first face F1. Hence, the distance between the facing face F21 and the first face F1 becomes narrower from the end part E1 of the glass substrate 10 to the center of the first face F1. Furthermore, the gap between the protrusion part 25 and the first face F1 is narrower than the distance between the facing face F21 and the first face F1.

The other configurations according to the sixth embodiment may be the same as those in the fifth embodiment. Consequently, according to the sixth embodiment, it is also possible to obtain the same effects as those of the fifth embodiment.

### Seventh Embodiment

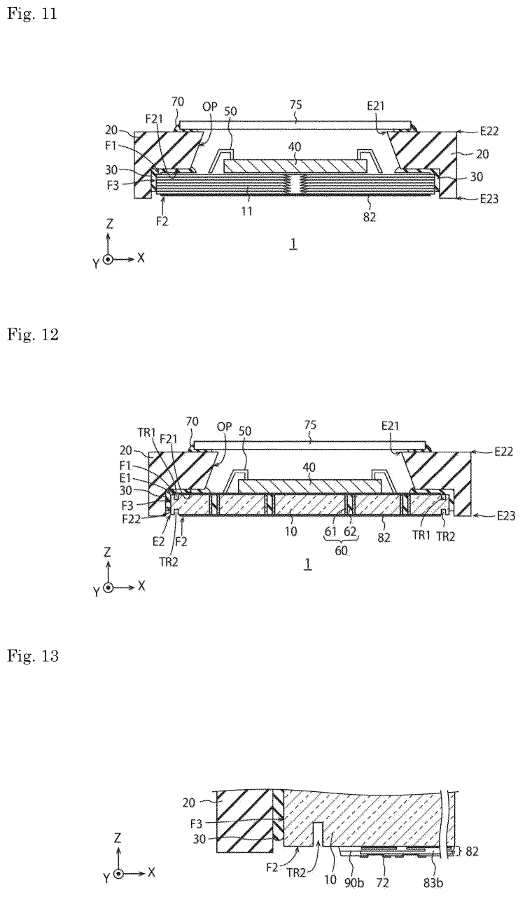

FIG. 11 is a schematic cross-sectional view illustrating a configuration example of the semiconductor device 1 according to the seventh embodiment.

In the seventh embodiment, a glass substrate 11 includes a plurality of the laminated glass substrates 10. The plurality of glass substrates 10 may each employ the same configuration as that of the glass substrate 10 according to the first embodiment. The glass substrate 11 is configured by laminating the plurality of these glass substrates 10. The other configurations according to the seventh embodiment may be the same as those in one of the first to sixth embodiments. Consequently, according to the seventh embodiment, it is also possible to obtain the same effects as those of the first to sixth embodiments.

### Eighth Embodiment

FIG. 12 is a schematic cross-sectional view illustrating a configuration example of the semiconductor device 1 according to the eighth embodiment. FIG. 13 is a partial cross-sectional view illustrating the configuration example of the semiconductor device 1 according to the eighth embodiment.

In the eighth embodiment, the glass substrate 10 includes trenches TR1 and TR2. The trench TR1 is formed at the outer edge part of the first face F1 of the glass substrate 10 and from the first face F1 to the second face F2. The trench TR2 is formed at the outer edge part of the second face F2 of the glass substrate 10 and from the second face F2 to the first face F1. The depths of the trenches TR1 and TR2 are less than ½ of the thickness of the glass substrate 10. When, for example, the thickness of the glass substrate 10 is 800 μm, the depths of the trenches TR1 and TR2 are 8 μm or less.

Similar to the adhesive layer 30, the trenches TR1 and TR2 are provided over the entire outer periphery of the glass substrate 10 in plan view seen from the Z direction. On the other hand, the trenches TR1 and TR2 may be partially provided at the outer periphery of the glass substrate 10.

The trenches TR1 and TR2 prevent chipping and cracking of the outer edge part of the glass substrate 10 from progressing to the center part at which the semiconductor chip 40 is provided. Consequently, it is possible to improve the reliability of the semiconductor device 1. Note that the trenches TR1 and TR2 are provided on both of the first and second faces F1 and F2 of the glass substrate 10. However, the trenches TR1 and TR2 may be provided only on one of the first and second faces F1 and F2. Even in this case, it is possible to prevent progress of chipping and cracking of the outer edge part of the glass substrate 10 to some degree.

Furthermore, the trenches TR1 and TR2 hold back the material of the adhesive layer 30, and thereby prevents the adhesive layer 30 from protruding toward the semiconductor chip 40 from between the frame 20 and the glass substrate 10. Consequently, it is possible to prevent the adhesive layer 30 from contacting the bonding wire 50, and keep the reliability of the semiconductor device 1.

The other configurations according to the eighth embodiment may be the same as those in one of the first to seventh embodiments. Consequently, according to the eighth embodiment, it is also possible to obtain the same effects as those of one of the first to seventh embodiments.

### Ninth Embodiment

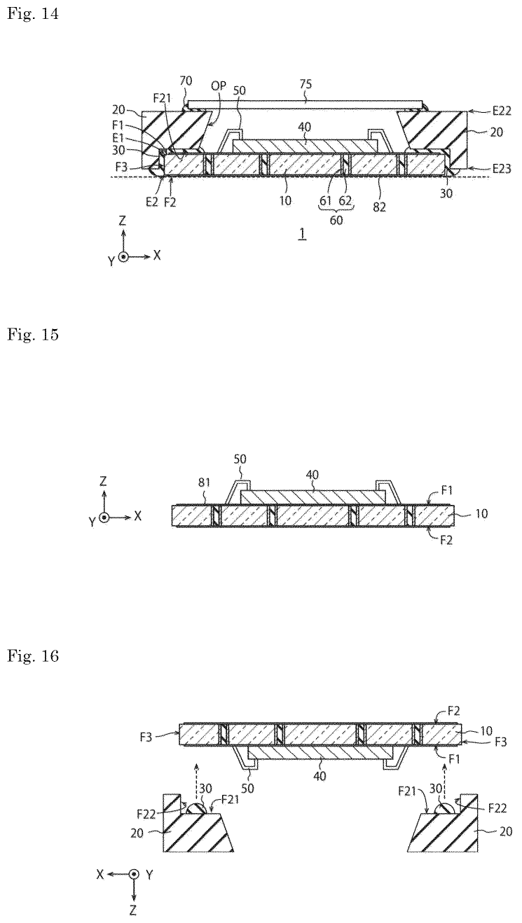

FIG. 14 is a schematic plan view illustrating a configuration example of the semiconductor device 1 according to the ninth embodiment.

In the ninth embodiment, the frame 20 extends to the middle of the side face F3 along the side face F3 from the end part E1 to the end part E2 of the glass substrate 10. The end part E23 of the frame 20 is located on an upper side (+Z direction) compared to the second face F2 of the glass substrate 10, and does not reach the second face F2. In this case, the frame 20 does not protect the end part E2 of the second face F2 of the glass substrate 10, yet protects the end part E1 of the first face F1.

Furthermore, in the ninth embodiment, the adhesive layer 30 extends to the lower side compared to the second face F2 along the side face F3 from the end part E1 to the end part E2 of the glass substrate 10. The adhesive layer 30 is provided substantially coplanarly to the second face F2 of the glass substrate 10. Although the frame 20 does not reach the second face F2 of the glass substrate 10, the adhesive layer 30 is provided substantially coplanarly to the second face F2, so that the adhesive layer 30 can protect the end part E2 of the glass substrate 10.

The other configurations according to the ninth embodiment may be the same as those in one of the first to eighth embodiments. Consequently, according to the ninth embodiment, it is also possible to obtain the same effects as those of the first to eighth embodiments.

### Manufacturing Method for Semiconductor Device 1

Next, a manufacturing method for the semiconductor device 1 will be described.

### Manufacturing Method 1

FIGS. 15 to 18 are cross-sectional views illustrating examples of the manufacturing method for the semiconductor device 1 according to the first embodiment.

First, as illustrated in FIG. 15, the semiconductor chip 40 is mounted on the first face F1 of the glass substrate 10. The bonding wire 50 connects the semiconductor chip 40 and the wiring part 81 of the glass substrate 10.

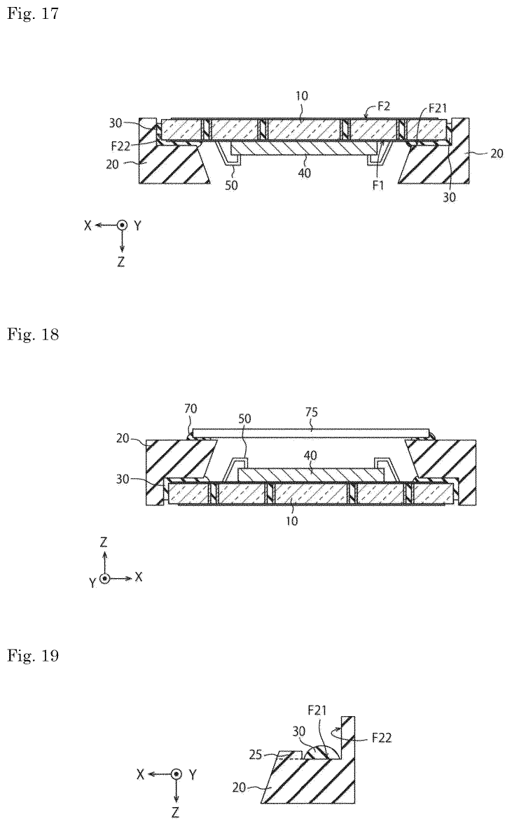

Next, as illustrated in FIG. 16, the material of the liquid adhesive layer 30 is supplied onto the facing face F21 of the frame 20. Next, the glass substrate 10 and the frame 20 are adhered using the adhesive layer 30 such that the facing face F21 faces the outer edge part of the first face F1, and the facing face F22 faces the side face F3 as illustrated in FIG. 17.

Next, as illustrated in FIG. 18, the cover glass 75 is adhered onto the frame 20 by the adhesive layer 70. Thus, the semiconductor device 1 according to the first embodiment is finished. Since the manufacturing method for the semiconductor device 1 according to the second to eighth embodiments can be easily understood from the manufacturing method according to the first embodiment, description thereof will be omitted.

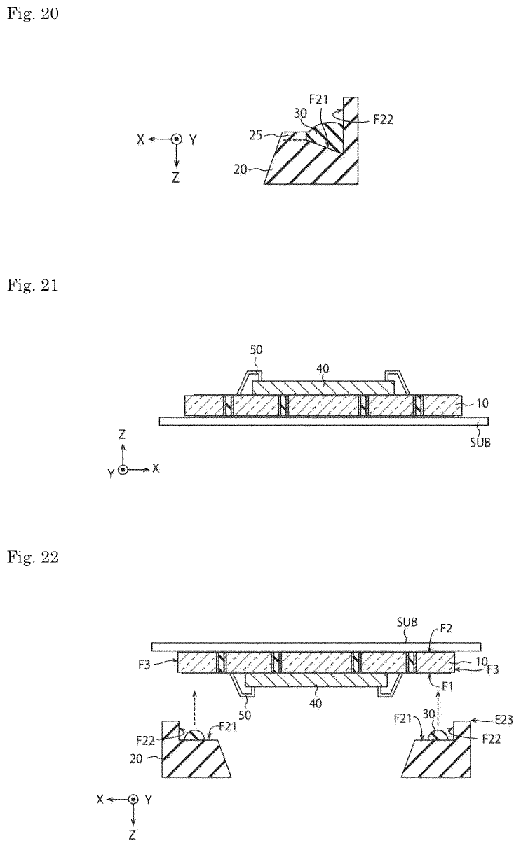

FIG. 19 is a cross-sectional view illustrating a state where the material of the liquid adhesive layer 30 is supplied onto the facing face F21 of the frame 20 according to the manufacturing method for the semiconductor device 1 according to the fifth embodiment. FIG. 20 is a cross-sectional view illustrating a state where the material of the liquid adhesive layer 30 is supplied onto the facing face F21 of the frame 20 according to the manufacturing method for the semiconductor device 1 according to the sixth embodiment.

In the fifth and sixth embodiments, the frame 20 includes the protrusion parts 25. Hence, when the adhesive layer 30 is supplied onto the facing face F21 of the frame 20, the protrusion parts 25 hold back the material of the adhesive layer 30. Consequently, it is possible to prevent the material of the adhesive layer 30 from flowing down from the facing face F21.

Next, the manufacturing method for the semiconductor device 1 according to the ninth embodiment will be described next.

### Manufacturing Method 2

FIGS. 21 to 24 are cross-sectional views illustrating examples of the manufacturing method for the semiconductor device 1 according to the ninth embodiment.

First, as described with reference to FIG. 15, the semiconductor chip 40 is mounted on the first face F1 of the glass substrate (Glass Interposer (GIP)) 10. The bonding wire 50 connects the semiconductor chip 40 and the wiring part 81 of the glass substrate 10.

Next, as illustrated in FIG. 21, the glass substrate 10 is attached onto a support base SUB.

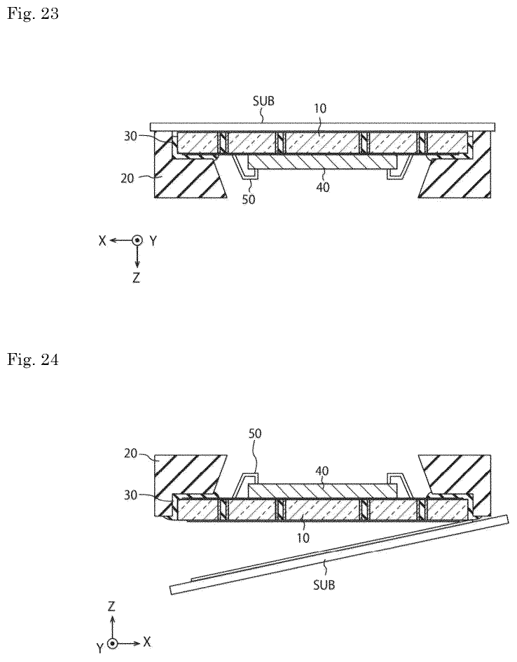

Next, as illustrated in FIG. 22, the material of the liquid adhesive layer 30 is supplied onto the facing face F21 of the frame 20. Next, as illustrated in FIG. 23, the glass substrate 10 and the frame 20 are adhered using the adhesive layer 30 such that the facing face F21 faces the outer edge part of the first face F1, and the facing face F22 faces the side face F3.

When the glass substrate 10 and the frame 20 are adhered, the end part E23 of the frame 20 does not protrude from the second face F2 toward a support base SUB side, the material of the adhesive layer 30 protrudes between the support base SUB and the frame 20 to some degree. Consequently, the adhesive layer 30 is filled partially between the support base SUB and the frame 20, and the adhesive layer 30 becomes substantially coplanar to the second face F2 of the glass substrate 10.

Next, as illustrated in FIG. 24, the support base SUB is separated from the glass substrate 10.

Next, as described with reference to FIG. 18, the cover glass 75 is adhered onto the frame 20 by the adhesive layer 70. Thus, the semiconductor device 1 according to the ninth embodiment is finished.

Consequently, by using the support base SUB, it is possible to form the adhesive layer 30 coplanarly to the second face F2 of the glass substrate 10.

### Manufacturing Method 3

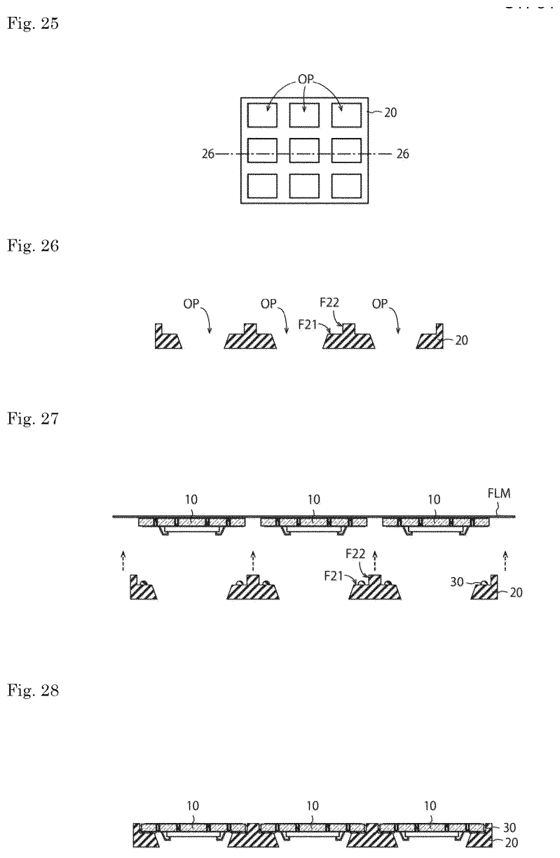

FIGS. 25 to 28 are views illustrating other examples of the manufacturing method for the semiconductor device 1 according to the first embodiment. According to this manufacturing method, at a beginning, the frames 20 form an aggregate while meeting a plurality of semiconductor devices 1 to simultaneously manufacture the plurality of semiconductor devices 1.

FIG. 25 is a plan view illustrating an example of the aggregate of the frames 20. FIG. 26 is a cross-sectional view taken along line 26-26 in FIG. 25.

First, the aggregate of the frames 20 illustrated in FIGS. 25 and 26 is prepared. The aggregate of the frames 20 includes a plurality of the opening parts OP at positions meeting a plurality of semiconductor chips 40 and the plurality of glass substrates 10.

Next, as illustrated in FIG. 27, the plurality of glass substrates 10 are attached onto a film FLM, and the material of the liquid adhesive layer 30 is supplied onto the facing face F21 of the frame 20. Next, the glass substrate 10 and the frame 20 are adhered using the adhesive layer 30 such that the facing face F21 faces the outer edge part of the first face F1, and the facing face F22 faces the side face F3. In this case, the plurality of glass substrates 10 on the film FLM are directed to and associated with the respective opening parts OP of the aggregate of the frames 20 to adhere the glass substrates 10 to the aggregate of the frames 20 by the adhesive layer 30.

Next, by separating the film FLM, the plurality of glass substrates 10 are adhered to the respective frames 20 as illustrated in FIG. 28.

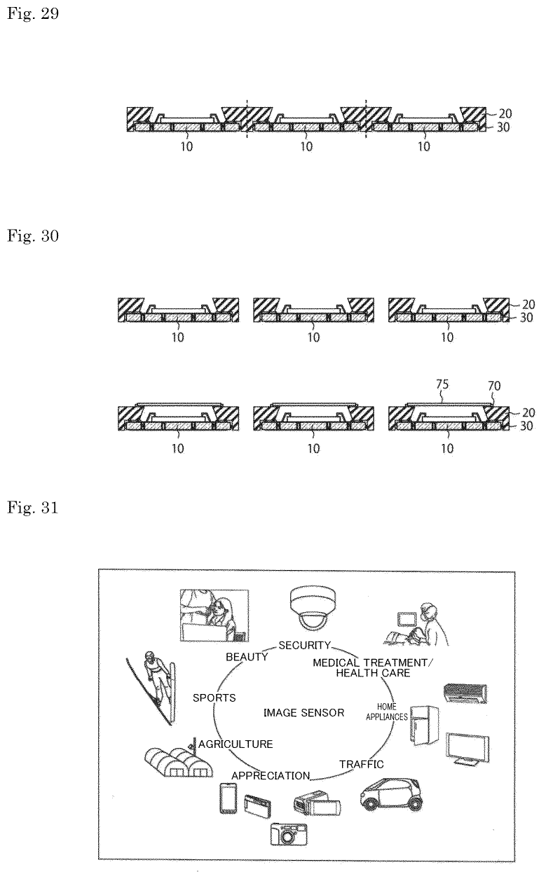

Next, as illustrated in FIG. 29, the aggregate of the frames 20 is diced using a dicing cutter or the like. Consequently, as illustrated in FIG. 30, the aggregate of the frames 20 is singulated as the frame 20 of each semiconductor device 1.

Subsequently, as described with reference to FIG. 18, the cover glass 75 is adhered onto the frame 20 by the adhesive layer 70. Thus, the semiconductor device 1 according to the first embodiment is finished. Since the manufacturing method for the semiconductor device 1 according to the second to ninth embodiments can be easily understood from the manufacturing method according to the first embodiment, description thereof will be omitted.

Note that, when the end part E23 of the frame 20 protrudes to the lower side compared to the second face F2 of the glass substrate 10, the frame 20 contacts the support base SUB or the film FLM, and therefore it is not preferable to manufacture semiconductor devices using the manufacturing methods 2 and 3.

### Example of Use of Imaging Device to Which Present Technology is Applied

FIG. 31 is a diagram illustrating an example where the embodiments according to the present technology are used as a CMOS image sensor.

The imaging devices according to the above embodiments can be used in various cases where light such as visible light, infrared light, ultraviolet light, and X rays is sensed as follows, for example. Specifically, as illustrated in FIG. 31, the above embodiments can be used for devices used in, for example, the field of appreciation in which an image provided for appreciation is captured, the field of traffic, the field of home appliances, the field of medical treatment and health care, the field of security, the field of beauty, the field of sports, and the field of agriculture.

Specifically, in a field of appreciation, the above embodiments can be used in devices for capturing an image provided for appreciation such as a digital camera, a smartphone, and a mobile phone with a camera function, for example.

In the field of traffic, for safe driving such as automatic stop and recognition of a driver's conditions, the above embodiments can be used for devices provided for traffic such as an in-vehicle sensor that captures images of the front, rear, surroundings, and inside of a vehicle, a monitoring camera that monitors traveling vehicles and roads, and a distance measuring sensor that measures a distance between vehicles or the like.

In the field of home appliances, the above embodiments can be used for devices provided for home appliances such as a television receiver, a refrigerator, and an air conditioner in order to capture an image of a user's gesture and operate equipment in response to the gesture.

In the field of medical treatment and health care, the above embodiments can be used for devices provided for medical treatment and health care such as an endoscope and a device that performs angiography by receiving infrared light.

In the field of security, the above embodiments can be used for devices provided for security such as a surveillance camera for crime prevention and a camera for person authentication.

In the field of beauty, the above embodiments can be used for devices provided for beauty such as a skin measuring instrument that captures images of skins and a microscope that captures images of scalps.

In the field of sports, the above embodiments can be used for devices provided for sports such as an action camera and a wearable camera for sports applications.

In the field of agriculture, the above embodiments can be used for devices provided for agriculture such as a camera that monitors the conditions of fields and crops.

Note that the present technology may also have the following configurations.

(1) A semiconductor device includes:
a glass substrate that includes a first face, a second face on a side opposite to the first face, and a first side face between the first face and the second face;
a semiconductor chip that is provided on the first face;
a frame that includes a first facing face facing an outer edge part of the first face, and a second facing face facing the first side face; and
a first material film that is provided at least partially between the glass substrate and the frame.

(2) In the semiconductor device described in (1), the frame covers a first end part between the first face and the first side face of the glass substrate, and over an entire outer periphery of the first face.

(3) In the semiconductor device described in (1) or (2), the frame extends to a lower side compared to the second face along the first side face from a first end part between the first face and the first side face of the glass substrate to a second end part between the second face and the first side face of the glass substrate.

(4) In the semiconductor device described in (1) or (2), the frame extends to a middle of the first side face along the first side face from a first end part between the first face and the first side face of the glass substrate to a second end part between the second face and the first side face of the glass substrate.

(5) In the semiconductor device described in any one of (1) to (4), the first material film is provided at the first end part between the first face and the first side face of the glass substrate and over an entire outer periphery of the glass substrate.

(6) In the semiconductor device described in any one of (1) to (4),
the semiconductor chip is a CMOS Image Sensor (CIS), and
a region of the frame facing a center part of the first face is provided with an opening part.

(7) In the semiconductor device described in any one of (1) to (6), the first material film extends to a lower side compared to the second face along the first side face from a first end part between the first face and the first side face of the glass substrate to a second end part between the second face and the first side face of the glass substrate.

(8) In the semiconductor device described in any one of (1) to (6), the first material film extends to a middle of the first side face along the first side face from a first end part between the first face and the first side face of the glass substrate to a second end part between the second face and the first side face of the glass substrate.

(9) The semiconductor device described in (7) or (8) further includes a second wiring provided on the second face, and
the first material film covers part of the second end part and the second wiring.

(10) The semiconductor device described in (7) or (8) further includes a second wiring provided on the second face, and
the first material film covers the second end part, and does not reach the second wiring.

(11) In the semiconductor device described in any one of (1) to (10), the frame includes a hole that penetrates from an outside in the first facing face, the second facing face, or a corner part between the first facing face and the second facing face.

(12) In the semiconductor device described in any one of (1) to (11), the frame includes at part of the first facing face a protrusion part that protrudes toward the first face of the glass substrate.

(13) In the semiconductor device described in any one of (1) to (12),
the first facing face of the frame is substantially parallel to the first face of the glass substrate, and
the second facing face of the frame is substantially parallel to the second face of the glass substrate.

(14) In the semiconductor device described in any one of (1) to (12), the first facing face of the frame is inclined with respect to the first face to approach the first face of the glass substrate from the first end part of the glass substrate to a center of the first face.

(15) In the semiconductor device described in any one of (1) to (14), a plurality of the glass substrates are laminated.

(16) In the semiconductor device described in any one of (1) to (15), the glass substrate includes a trench provided in the first face or the second face.

(17) In the semiconductor device described in (1), the first material film is provided substantially coplanarly to the second face of the glass substrate.

(18) A manufacturing method for a semiconductor device includes:
mounting a semiconductor chip on a first face of a glass substrate that includes the first face, a second face on a side opposite to the first face, and a first side face between the first face and the second face;
supplying a first material film to a first facing face of a frame including the first facing face and a second facing face; and
adhering the glass substrate and the frame using the first material film such that the first facing face faces an outer edge part of the first face, and the second facing face faces the first side face.

(19) The manufacturing method for the semiconductor device described in (18) further includes attaching the glass substrate onto a support member, and
when the semiconductor chip and the frame are adhered, the glass substrate on the support member is directed and adhered to the frame using the first material film.

(20) According to the manufacturing method for the semiconductor device described in (19), when the semiconductor chip and the frame are adhered, the support member makes the first material film substantially coplanarly to the second face of the glass substrate.

(21) According to the manufacturing method for the semiconductor device described in (19), a plurality of the glass substrates are attached to the support member, the frame includes an opening part at a position meeting each of the plurality of the glass substrates, and
when the semiconductor chip and the frame are adhered, the plurality of the glass substrates on the support member are directed and adhered to the opening part of the frame using the first material film.

Note that the present disclosure is not limited to the above-described embodiments, and various modifications can be made without departing from the gist of the present disclosure. The advantageous effects described in the present specification are merely exemplary and are not limited, and other advantageous effects may be achieved.

### REFERENCE SIGNS LIST

10 Glass substrate
20 Frame
30 Adhesive layer
40 Semiconductor chip
50 Bonding wire
60 Through-electrode
61 Metal film
62 Insulating film
81, 82 Wiring part
70 Adhesive layer
75 Cover glass

1. A semiconductor device comprising:
a glass substrate that includes a first face, a second face on a side opposite to the first face, and a first side face between the first face and the second face;
a semiconductor chip that is provided on the first face;
a frame that includes a first facing face facing an outer edge part of the first face, and a second facing face facing the first side face; and
a first material film that is provided at least partially between the glass substrate and the frame.

2. The semiconductor device according to claim 1, wherein the frame covers a first end part between the first face and the first side face of the glass substrate, and over an entire outer periphery of the first face.

3. The semiconductor device according to claim 1, wherein the frame extends to a lower side compared to the second face along the first side face from a first end part between the first face and the first side face of the glass substrate to a second end part between the second face and the first side face of the glass substrate.

4. The semiconductor device according to claim 1, wherein the frame extends to a middle of the first side face along the first side face from a first end part between the first face and the first side face of the glass substrate to a second end part between the second face and the first side face of the glass substrate.

5. The semiconductor device according to claim 1, wherein the first material film is provided at a first end part between the first face and the first side face of the glass substrate and over an entire outer periphery of the glass substrate.

6. The semiconductor device according to claim 1, wherein
the semiconductor chip is a CMOS Image Sensor (CIS), and
a region of the frame facing a center part of the first face is provided with an opening part.

7. The semiconductor device according to claim 1, wherein the first material film extends to a lower side compared to the second face along the first side face from a first end part between the first face and the first side face of the glass substrate to a second end part between the second face and the first side face of the glass substrate.

8. The semiconductor device according to claim 1, wherein the first material film extends to a middle of the first side face along the first side face from a first end part between the first face and the first side face of the glass substrate to a second end part between the second face and the first side face of the glass substrate.

9. The semiconductor device according to claim 7 further comprising a second wiring provided on the second face,
wherein the first material film covers part of the second end part and the second wiring.

10. The semiconductor device according to claim 7, further comprising a second wiring provided on the second face,
wherein the first material film covers the second end part, and does not reach the second wiring.

11. The semiconductor device according to claim 1, wherein the frame includes a hole that penetrates from an outside in the first facing face, the second facing face, or a corner part between the first facing face and the second facing face.

12. The semiconductor device according to claim 1, wherein the frame includes at part of the first facing face a protrusion part that protrudes toward the first face of the glass substrate.

13. The semiconductor device according to claim 1, wherein
the first facing face of the frame is substantially parallel to the first face of the glass substrate, and
the second facing face of the frame is substantially parallel to the second face of the glass substrate.

14. The semiconductor device according to claim 1, wherein the first facing face of the frame is inclined with respect to the first face to approach the first face of the glass substrate from the first end part of the glass substrate to a center of the first face.

15. The semiconductor device according to claim 1, wherein a plurality of the glass substrates are laminated.

16. The semiconductor device according to claim 1, wherein the glass substrate includes a trench provided in the first face or the second face.

17. The semiconductor device according to claim 1, wherein the first material film is provided substantially coplanarly to the second face of the glass substrate.

18. A manufacturing method for a semiconductor device comprising:
mounting a semiconductor chip on a first face of a glass substrate that includes the first face, a second face on a side opposite to the first face, and a first side face between the first face and the second face;
supplying a first material film to a first facing face of a frame including the first facing face and a second facing face; and
adhering the glass substrate and the frame using the first material film such that the first facing face faces an outer edge part of the first face, and the second facing face faces the first side face.

19. The manufacturing method for the semiconductor device according to claim 18 further comprising attaching the glass substrate onto a support member, wherein, when the semiconductor chip and the frame are adhered, the glass substrate on the support member is directed and adhered to the frame using the first material film.

20. The manufacturing method for the semiconductor device according to claim 19, wherein, when the semiconductor chip and the frame are adhered, the support member makes the first material film substantially coplanarly to the second face of the glass substrate.

21. The manufacturing method for the semiconductor device according to claim 19, wherein
a plurality of the glass substrates are attached to the support member,
the frame includes an opening part at a position meeting each of the plurality of the glass substrates, and
when the semiconductor chip and the frame are adhered, the plurality of the glass substrates on the support member are directed and adhered to the opening part of the frame using the first material film.
